(19) United States
(12) Patent Application Publication
(10) Pub. No.: US 2024/0008257 A1
(43) Pub. Date: Jan. 4, 2024

(54) SEMICONDUCTOR DEVICE

(71) Applicant: Kioxia Corporation, Tokyo (JP)

(72) Inventors: Takuya KIKUCHI, Yokkaichi Mie (JP); Masanori MIZUKOSHI, Yokkaichi Mie (JP); Ken SHIMOMORI, Yokkaichi Mie (JP)

(73) Assignee: Kioxia Corporation, Tokyo (JP)

(21) Appl. No.: 18/180,792

(22) Filed: Mar. 8, 2023

(30) Foreign Application Priority Data
Jun. 30, 2022 (JP) 2022-106076

(51) Int. Cl. H10B 12/00

(52) U.S. Cl. CPC H10B 12/33; H10B 12/05

(57) ABSTRACT

A semiconductor device includes: a first and a second insulating layer; a first conductive layer; an oxide semiconductor layer; and a third insulating layer disposed between the first insulating layer, the second insulating layer, and the first conductive layer; and the oxide semiconductor layer. The third insulating layer includes: a first part that covers a part of a side surface of the first insulating layer; and a second part that covers a part of side surfaces of the second insulating layer and the first conductive layer. A region extending in a direction different from an extending direction of the first and the second part is disposed. The region is disposed between a region corresponding to the first part and a region corresponding to the second part in a contact surface between the third insulating layer and the oxide semiconductor layer.

### CROSS-REFERENCE TO RELATED APPLICATIONS

This application is based upon and claims the benefit of Japanese Patent Application No. 2022-106076, filed on Jun. 30, 2022, the entire contents of which are incorporated herein by reference.

### BACKGROUND

### Field

Embodiments described herein relate generally to a semiconductor device.

### Description of the Related Art

There has been known a semiconductor device that includes a first insulating layer and a second insulating layer arranged in a first direction, a first conductive layer disposed between the first insulating layer and the second insulating layer, and an oxide semiconductor layer extending in the first direction and opposed to the first insulating layer, the second insulating layer, and the first conductive layer in a second direction intersecting with the first direction.

### BRIEF DESCRIPTION OF THE DRAWINGS

FIG. 1 is a schematic circuit diagram illustrating a configuration of a part of a semiconductor device according to a first embodiment;

FIG. 2 is a schematic cross-sectional view illustrating a configuration of a part of the semiconductor device;

FIG. 3 is a schematic plan view illustrating a configuration of a part of the semiconductor device;

FIG. 4 is a schematic plan view illustrating a configuration of a part of the semiconductor device;

FIG. 5 is a schematic cross-sectional view illustrating a configuration of a part of the semiconductor device;

FIG. 6 is a schematic cross-sectional view illustrating a configuration of a part of the semiconductor device;

FIG. 7 is a schematic cross-sectional view for describing a manufacturing method of the semiconductor device;

FIG. 8 is a schematic cross-sectional view for describing the manufacturing method;

FIG. 9 is a schematic cross-sectional view for describing the manufacturing method;

FIG. 10 is a schematic cross-sectional view for describing the manufacturing method;

FIG. 11 is a schematic cross-sectional view for describing the manufacturing method;

FIG. 12 is a schematic cross-sectional view for describing the manufacturing method;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view illustrating a configuration of a part of the semiconductor device according to a comparative example;

FIG. 17 is a schematic cross-sectional view for describing the manufacturing method of the semiconductor device according to the comparative example;

FIG. 18 is a schematic cross-sectional view for describing the manufacturing method of the semiconductor device according to the comparative example;

FIG. 19 is a schematic cross-sectional view illustrating a configuration of a part of Modification 1 of the semiconductor device according to the first embodiment;

FIG. 20 is a schematic cross-sectional view for describing a manufacturing method of the modification;

FIG. 21 is a schematic cross-sectional view illustrating a configuration of a part of Modification 2 of the semiconductor device according to the first embodiment;

FIG. 22 is a schematic cross-sectional view illustrating a configuration of a part of the modification;

FIG. 23 is a schematic cross-sectional view for describing the manufacturing method of the modification;

FIG. 24 is a schematic cross-sectional view for describing the manufacturing method of the modification;

FIG. 25 is a schematic cross-sectional view for describing the manufacturing method of the modification;

FIG. 26 is a schematic cross-sectional view for describing the manufacturing method of the modification;

FIG. 27A is a schematic cross-sectional view illustrating a configuration of a part of the semiconductor device according to a second embodiment;

FIG. 27B is a schematic cross-sectional view illustrating a configuration of a part of the semiconductor device according to the second embodiment;

FIG. 28 is a schematic cross-sectional view for describing the manufacturing method of the semiconductor device;

FIG. 29 is a schematic cross-sectional view for describing the manufacturing method;

FIG. 30 is a schematic cross-sectional view illustrating a configuration of a part of a semiconductor device according to a third embodiment;

FIG. 31 is a schematic cross-sectional view illustrating a configuration of a part of the semiconductor device;

FIG. 32 is a schematic cross-sectional view for describing the manufacturing method of the semiconductor device;

FIG. 33 is a schematic cross-sectional view for describing the manufacturing method; and

FIG. 34 is a schematic cross-sectional view illustrating a configuration of a part of a semiconductor device according to a fourth embodiment.

### DETAILED DESCRIPTION

A semiconductor device according to one embodiment comprises: a first insulating layer and a second insulating layer arranged in a first direction; a first conductive layer disposed between the first insulating layer and the second insulating layer; an oxide semiconductor layer extending in the first direction, the oxide semiconductor layer being opposed to the first insulating layer, the second insulating layer, and the first conductive layer in a second direction intersecting with the first direction; and a third insulating layer disposed between the first insulating layer and the oxide semiconductor layer, between the second insulating layer and the oxide semiconductor layer, and between the first conductive layer and the oxide semiconductor layer. The third insulating layer includes: a first part that covers at least a part of a side surface in the second direction of the first insulating layer; and a second part that covers at least a part of side surfaces in the second direction of the second insulating layer and the first conductive layer. A first region extending in a direction different from an extending direction of the first part and an extending direction of the second part is disposed. The region is disposed between a region corresponding to the first part and a region corresponding to the second part, and is in contact with the third insulating layer and the oxide semiconductor layer.

Next, the semiconductor devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in OFF state, the first transistor is “electrically connected” to the third transistor.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion at a side opposite to the substrate of this configuration. A surface intersecting with the X-direction or the Y-direction is referred to as a side surface and the like.

### First Embodiment

[Circuit Configuration]

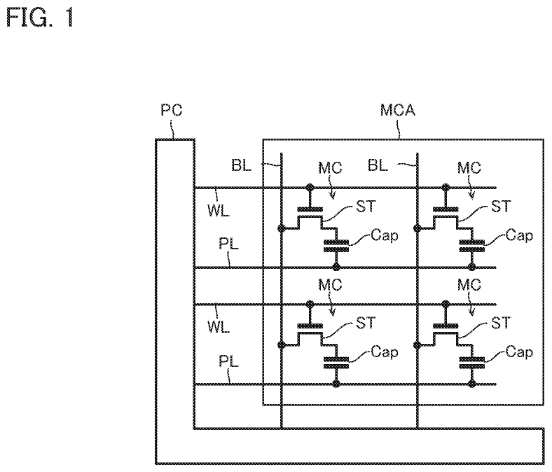

A semiconductor device according to the first embodiment, for example, includes memory cell arrays MCA and a peripheral circuit PC as illustrated in FIG. 1.

The memory cell array MCA includes a plurality of bit lines BL, a plurality of word lines WL, a plurality of plate lines PL, and a plurality of memory cells MC that are connected to the plurality of bit lines BL, the plurality of word lines WL, and the plurality of plate lines PL. A plurality of memory cells MC connected to one word line WL are connected to the respective mutually different bit lines BL. A plurality of memory cells MC connected to one bit line BL are connected to the respective mutually different word lines WL.

Each of the memory cells MC includes a select transistor ST and a capacitor Cap that are connected in series between the bit line BL and the plate line PL.

The select transistor ST is a field-effect type transistor including a semiconductor layer that functions as a channel region, a gate insulating film, and a gate electrode. Each gate electrode of the select transistor ST is connected to the word line WL.

The capacitor Cap includes a pair of electrodes and an insulating film including a memory portion.

The peripheral circuit PC includes, for example, a voltage generation circuit that generates an operating voltage and outputs the operating voltage to a voltage supply line, a decode circuit that electrically conducts a desired voltage supply line to each of the wirings (the bit lines BL, the word lines WL, and the plate lines PL) in the memory cell array MCA, a sense amplifier circuit that senses a current or a voltage of the bit lines BL, and the like.

[Structure]

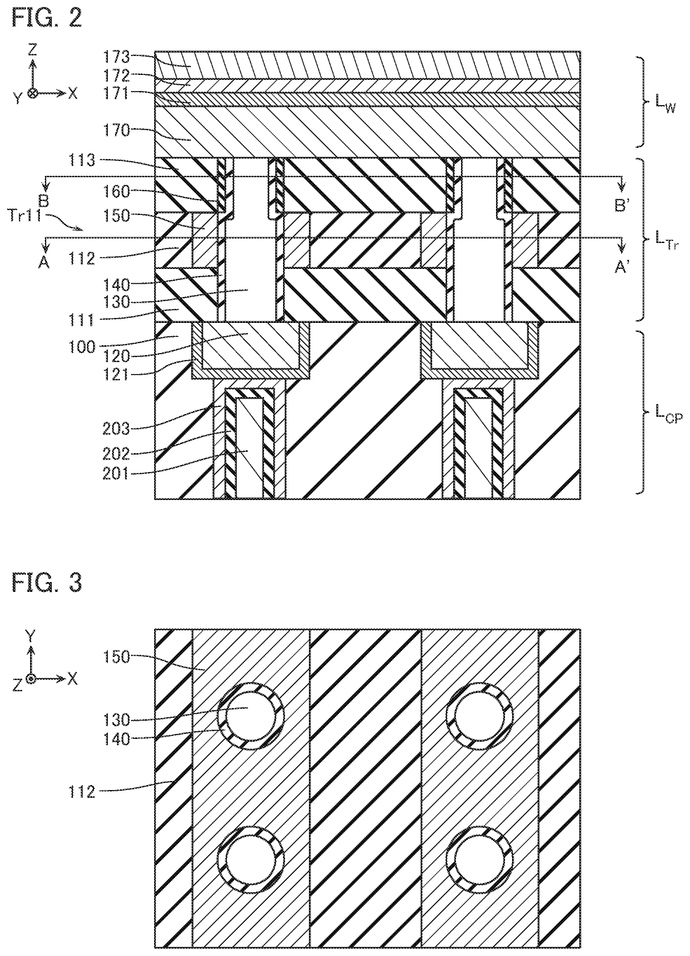

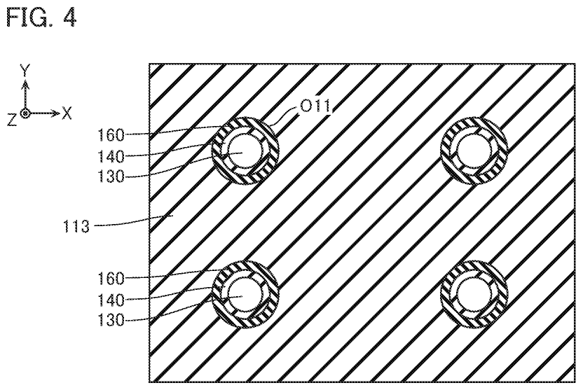

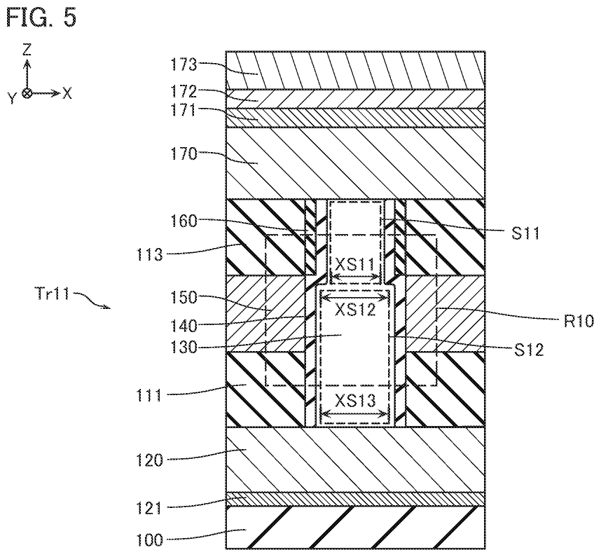

FIG. 2 is a schematic XZ cross-sectional view illustrating a configuration of a part of the semiconductor device. FIG. 3 is a schematic XY cross-sectional view cut the configuration illustrated in FIG. 2 along the line A-A′ and viewed along the arrow direction. FIG. 4 is a schematic XY cross-sectional view cut the configuration illustrated in FIG. 2 along the line B-B′ and viewed along the arrow direction.

The semiconductor device according to the first embodiment includes a transistor layer L_{Tr}, a capacitor layer L_{CP} disposed below the transistor layer L_{Tr}, and a wiring layer L_{W} disposed above the transistor layer L_{Tr}.

[Transistor Layer L_{Tr}]

For example, as illustrated in FIG. 2, the transistor layer L_{Tr} includes insulating layers 111 disposed on upper surfaces of insulating layers 100 and insulating layers 113 disposed above the insulating layers 111. Additionally, the transistor layer L_{Tr} includes a plurality of insulating layers 112 and a plurality of conductive layers 150 disposed between the insulating layers 111 and the insulating layers 113 and alternately arranged in the X-direction. Additionally, for example, as illustrated in FIG. 3, the transistor layer L_{Tr} includes a plurality of semiconductor layers 130 corresponding to the plurality of conductive layers 150 and arranged in the X-direction and the Y-direction, and insulating layers 140 disposed on outer peripheral surfaces of the semiconductor layers 130. For example, as illustrated in FIG. 2 and FIG. 4, the transistor layer L_{Tr} includes an insulating layer 160 disposed between the insulating layer 140 and the insulating layer 113.

The insulating layer 100, the insulating layer 111, the insulating layer 112, and the insulating layer 113 contain, for example, silicon oxide (SiO₂).

The semiconductor layer 130 is an oxide semiconductor, and, for example, functions as a channel region of the select transistor ST (FIG. 1). The semiconductor layer 130 contains, for example, zinc (Zn), oxygen (O), and at least one element selected from the group consisting of indium (In), gallium (Ga), silicon (Si), aluminum (Al), and tin (Sn). The semiconductor layer 130 contains, for example, indium (In), gallium (Ga), zinc (Zn), and oxygen (O).

The insulating layer 140, for example, functions as a gate insulating film of the select transistor ST (FIG. 1). The insulating layer 140 contains, for example, silicon oxide (SiO₂).

The conductive layers 150, for example, function as gate electrodes of the plurality of select transistors ST arranged in the Y-direction and the word lines WL (FIG. 1) of the memory cell array MCA. The conductive layer 150 may contain, for example, tungsten (W) or a stacked structure of titanium nitride (TiN) and tungsten (W).

For example, as illustrated in FIG. 2 and FIG. 4, the insulating layers 160 are disposed so as to cover side surfaces in the X-direction and the Y-direction of the insulating layers 113.

The insulating layer 160 may be disposed with a material different from the insulating layer 113, for example. In the case, the insulating layer 160 may contain, for example, silicon nitride (SiN).

The insulating layer 160 may be disposed with a material same as the insulating layer 113. In the case, for example, a film density of, for example, silicon oxide (SiO₂) constituting the insulating layer 113 and a film density of, for example, silicon oxide (SiO₂) constituting the insulating layer 160 are disposed to be mutually different. For example, the film density of the silicon oxide (SiO₂) constituting the insulating layer 160 may be larger than or smaller than the film density of the silicon oxide (SiO₂) constituting the insulating layer 113.

Note that the materials contained in the insulating layer 113 and the insulating layer 160 can be measured by Secondary Ion Mass Spectrometry (SIMS) or the like. The film densities of the materials contained in the insulating layer 113 and the insulating layer 160 can be measured by a method, such as Transmission Electron Microscopy (TEM)-Energy Dispersive X-ray Spectroscopy (EDX), and X-Ray Reflectivity measurement (XRR). For example, when both of the insulating layer 113 and the insulating layer 160 contain silicon oxide (SiO₂) and the film density in the insulating layer 113 differs from the film density in the insulating layer 160, in the measurement performed by TEM-EDX, a difference occurs in spectral intensity corresponding to one or the other of silicon (Si) and oxygen (O).

[Capacitor Layer L_{CP}]

For example, as illustrated in FIG. 2, the capacitor layer L_{CP} is disposed corresponding to the semiconductor layers 130, and includes a plurality of conductive layers 120 connected to lower ends of the semiconductor layers 130, and a plurality of conductive layers 121 disposed corresponding to the plurality of conductive layers 120 and disposed lower surfaces and outer peripheral surfaces of the plurality of conductive layers 120. Additionally, the capacitor layer L_{CP} includes a plurality of conductive layers 201 disposed corresponding to the plurality of conductive layers 120 and disposed below the plurality of conductive layers 120, insulating layers 202 disposed on upper surfaces and outer peripheral surfaces of the conductive layers 201, and conductive layers 203 disposed on upper surfaces and outer peripheral surfaces of the insulating layers 202.

The conductive layer 120, for example, functions as a drain electrode of the select transistor ST (FIG. 1). The conductive layer 120 may have an approximately circular shape in the XY cross-sectional surface and have a plug shape. The conductive layer 120 contains at least one of, for example, indium (In), tin (Sn), niobium (Nb), titanium (Ti), and tungsten (W). The conductive layer 120 may be, for example, indium tin oxide (InSnO).

The conductive layer 121, for example, may be titanium nitride (TiN).

The conductive layer 201 functions as one electrode of the capacitor Cap (FIG. 1). The conductive layer 201 includes, for example, a stacked structure of, for example, titanium nitride (TiN) and tungsten (W). The conductive layer 201 is electrically connected to a plate line PL (FIG. 1).

The insulating layer 202 functions as an insulating layer between electrodes of the capacitor Cap (FIG. 1). The insulating layer 202 contains, for example, silicon oxide (SiO₂). The insulating layer 202 may be, for example, alumina (Al₂O₃) or another insulating metal oxide.

The conductive layer 203, for example, functions as the other electrode of the capacitor Cap (FIG. 1). The conductive layer 203 includes, for example, a stacked structure of, for example, titanium nitride (TiN) and tungsten (W). The conductive layer 203 is connected to the lower end surface in the Z-direction of the conductive layer 121.

[Wiring Layer L_{W}]

The wiring layer L_{W} includes a conductive layer 170, a conductive layer 171, a conductive layer 172, and a conductive layer 173 disposed in the order on the upper surface of the transistor layer L_{Tr}. The conductive layers 170, the conductive layers 171, the conductive layers 172, and the conductive layers 173, for example, extend in the X-direction as illustrated in FIG. 2, and are plurally disposed in the Y-direction. The conductive layers 170, the conductive layers 171, the conductive layers 172, and the conductive layer 173, for example, function as source electrodes of the plurality of select transistors ST arranged in the X-direction and the bit lines BL (FIG. 1) of the memory cell array MCA. The conductive layer 170, for example, contains a material similar to the conductive layer 120. The conductive layer 171, for example, contains titanium nitride (TiN). The conductive layer 172, for example, contains tungsten (W). The conductive layer 173, for example, contains aluminum (Al).

[Shapes of Semiconductor Layer 130, Insulating Layer 140, and Insulating Layer 160]

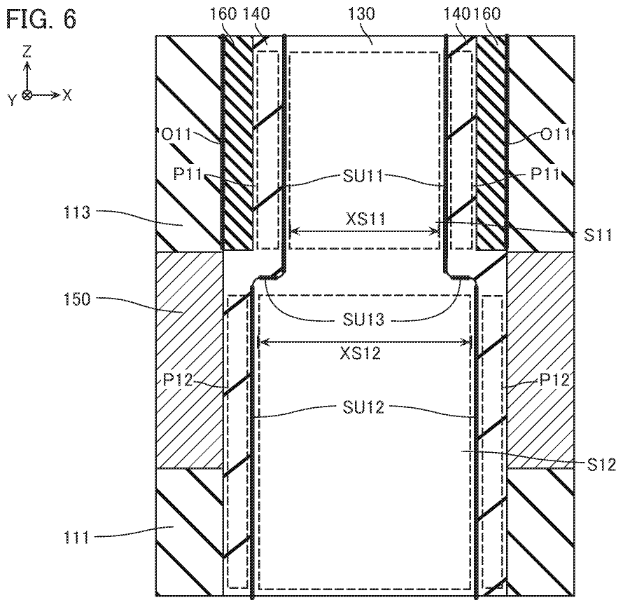

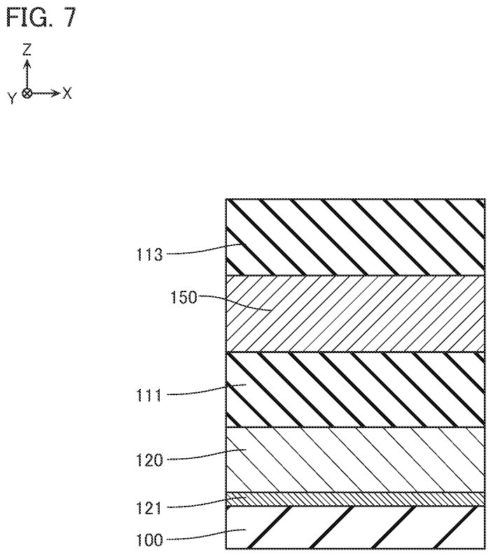

Next, the shapes of the semiconductor layer 130, the insulating layer 140, and the insulating layer 160 will be described with reference to FIG. 5 and FIG. 6. In the following description, a configuration achieving the select transistor ST (FIG. 1) will be referred to as a “transistor structure Tr11” in some cases. FIG. 5 and FIG. 6 are schematic XZ cross-sectional views illustrating a configuration of a part of the transistor structure Tr11. FIG. 6 is a schematic cross-sectional view illustrating an enlarged region R10 illustrated in FIG. 5.

For example, as illustrated in FIG. 6, the insulating layer 140 includes a part P11. The part P11 covers a side surface in the X-direction of the insulating layer 113 via the insulating layer 160. Additionally, the insulating layer 140 includes a part P12. The part P12 contacts the insulating layer 111 and the conductive layer 150 and covers the side surfaces in the X-direction of the insulating layer 111 and the conductive layer 150. Each of the part P11 and the part P12 extends in the Z-direction.

In the contact surface of the insulating layer 140 with the semiconductor layer 130, a region corresponding to the part P11 is referred to as a surface Still and a region corresponding to the part P12 is referred to as a surface SU12. Additionally, in this embodiment, a surface SU13 is disposed in a region between the surface Still and the surface SU12. The surface SU13 extends in a direction different from the extending direction (the Z-direction in the example of FIG. 6) of the part P11 and the part P12. For example, in the example of FIG. 6, the surface SU13 extends in the X-direction.

For example, as illustrated in FIG. 6, the semiconductor layer 130 includes a region S11 having an outer peripheral surface surrounded by the part P11 of the insulating layer 140 and a region S12 having an outer peripheral surface surrounded by the part P12 of the insulating layer 140. A width in the X-direction of the lower end portion (the end portion on the region S12 side in the Z-direction) of the region S11 is a width XS11. A width in the X-direction of the upper end portion (the end portion on the region S11 side in the Z-direction) of the region S12 is a width XS12. The width XS11 is smaller than the width XS12.

Note that, for example, as illustrated in FIG. 5, a width in the X-direction of the lower end portion (the end portion on the side opposite to the region S11 in the Z-direction) of the region S12 in the semiconductor layer 130 is a width XS13. The width XS13 may be the same extent to the width XS12 or may be smaller than the width XS12.

For example, as illustrated in FIG. 4 to FIG. 6, the insulating layer 160 is disposed on a surface O11 as an opposed surface of the insulating layer 113 to the semiconductor layer 130. While the surface O11 is in contact with the insulating layer 160, the surface O11 is not in contact with the insulating layer 140. That is, the insulating layer 113 is not in contact with the insulating layer 140.

In the description above, the transistor structure Tr11 in the XZ cross-sectional surface as illustrated in, for example, FIG. 5 and FIG. 6 has been exemplified. However, the transistor structure Tr11 may have the similar configuration in the YZ cross-sectional surface (not illustrated).

### Manufacturing Method of First Embodiment

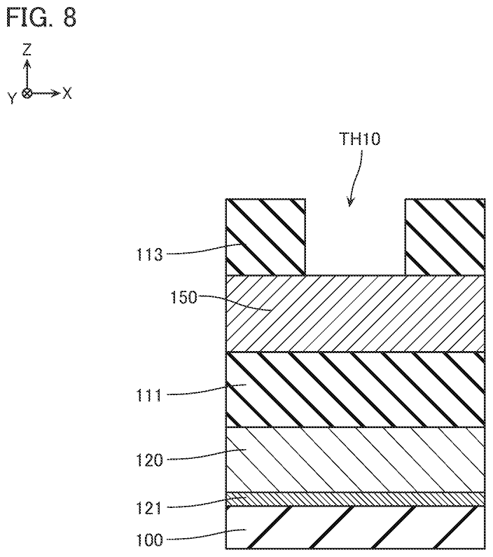

Next, with reference to FIG. 7 to FIG. 15, the manufacturing method of the semiconductor device according to this embodiment will be described. FIG. 7 to FIG. 15 are schematic cross-sectional views for describing the manufacturing method of the semiconductor device according to the first embodiment and correspond to the part illustrated in FIG. 5.

In the manufacturing method, for example, as illustrated in FIG. 7, the insulating layer 100, the conductive layer 121, the conductive layer 120, the insulating layer 111, the conductive layer 150, and the insulating layer 113 are formed above a substrate (not illustrated) in the order. This process is performed by, for example, Chemical Vapor Deposition (CVD).

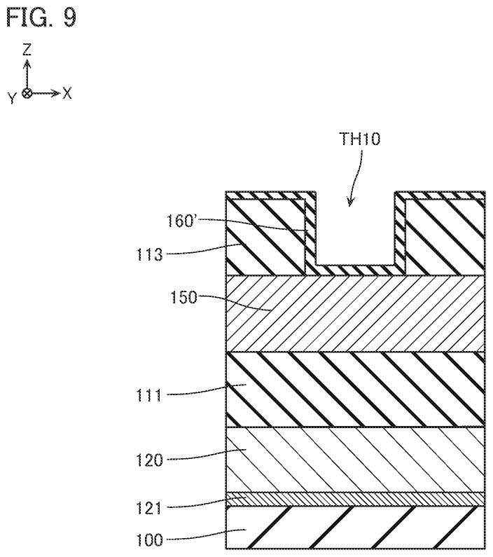

Next, for example, as illustrated in FIG. 8, an opening TH10 is formed in the insulating layer 113. The opening TH10 extends in the Z-direction to expose the conductive layer 150. In this process, for example, an insulating layer having an opening in a part corresponding to the opening TH10 is formed on the upper surface of the structure illustrated in FIG. 7, and, for example, Reactive Ion Etching (RIE) is performed using it as a mask.

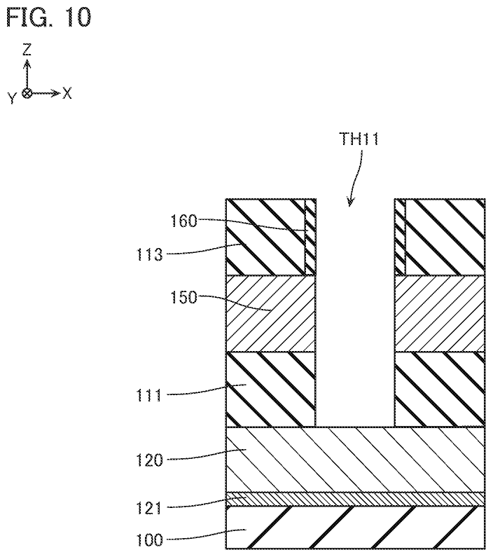

Next, for example, as illustrated in FIG. 9, an insulating layer 160′ is formed on the upper surface of the insulating layer 113 and inside the opening TH10. The insulating layer 160′, for example, contains a material similar to the insulating layer 160. This process is performed by, for example, Atomic Layer Deposition (ALD), wet coating, or CVD.

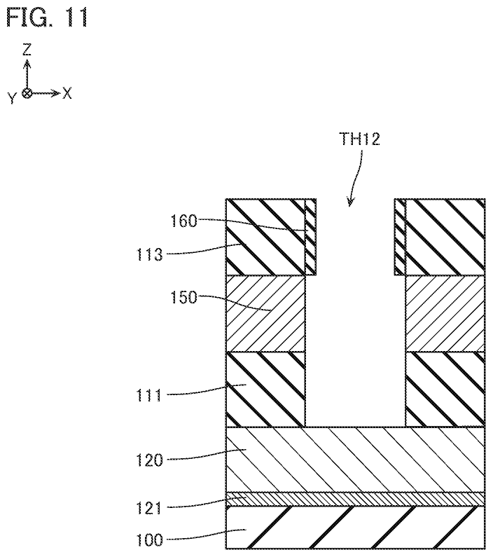

Next, for example, as illustrated in FIG. 10, an opening TH11 is formed in the part where the opening TH10 was present. The opening TH11 extends in the Z-direction and penetrates the conductive layer 150 and the insulating layer 111 to expose the conductive layer 120. In this process, in the insulating layer 160′, the upper surface part of the insulating layer 113 and the bottom surface part of the opening TH10 are removed, and the insulating layer 160 is formed on the side surface of the insulating layer 113 inside the opening TH11. This process is performed by, for example, RIE. Note that this process is performed under a condition in which the insulating layer 111 and the conductive layer 150 are removed easier than the insulating layer 160′.

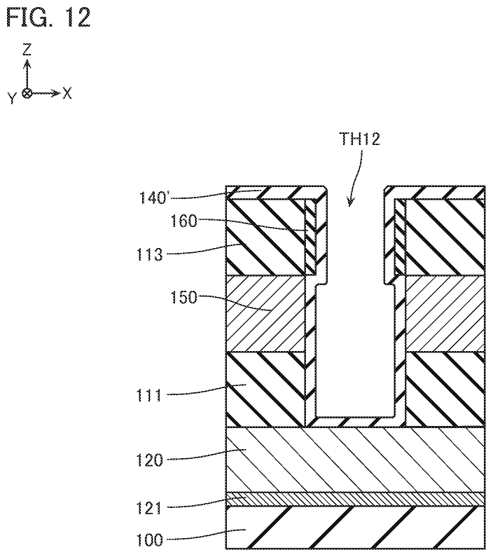

Next, for example, as illustrated in FIG. 11, via the opening TH11, the parts of the conductive layer 150 and the insulating layer 111 exposed to the opening TH11 are removed to form an opening TH12. Note that, in this process, the insulating layer 113 is protected by the insulating layer 160. This process is performed by, for example, Chemical Dry Etching (CDE) or wet etching.

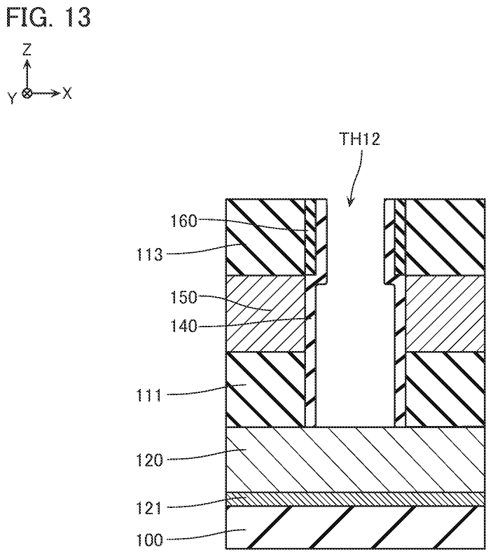

Next, for example, as illustrated in FIG. 12, an insulating layer 140′ is formed on the upper surface of the insulating layer 113 and inside the opening TH12. The insulating layer 140′, for example, contains a material similar to the insulating layer 140. This process is performed by, for example, ALD or CVD.

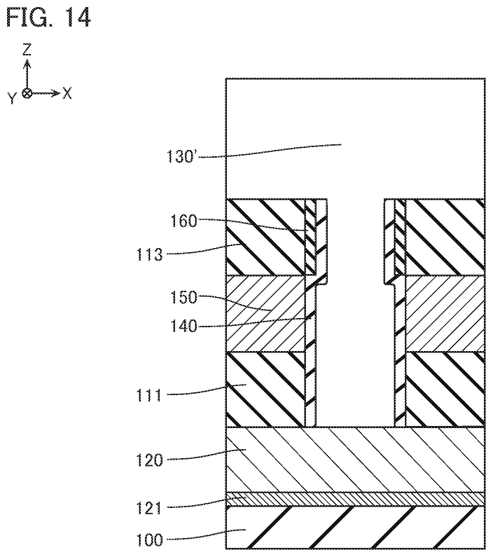

Next, for example, as illustrated in FIG. 13, in the insulating layer 140′, the upper surface part of the insulating layer 113 and the bottom surface part of the opening TH12 are removed to form an insulating layer 140 on the inner surface of the opening TH12. This process exposes the conductive layer 120 to the bottom surface of the opening TH12. This process is performed by, for example, RIE.

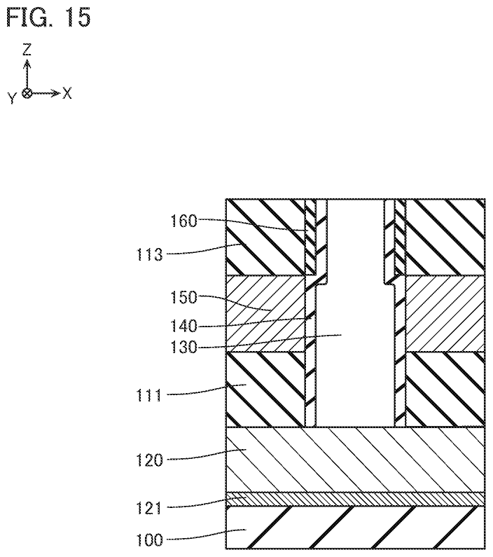

Next, for example, as illustrated in FIG. 14, a semiconductor layer 130′ is formed inside the opening TH12 and on the upper surface of the insulating layer 113. The semiconductor layer 130′, for example, contains a material similar to the semiconductor layer 130. This process is performed by, for example, sputtering or CVD.

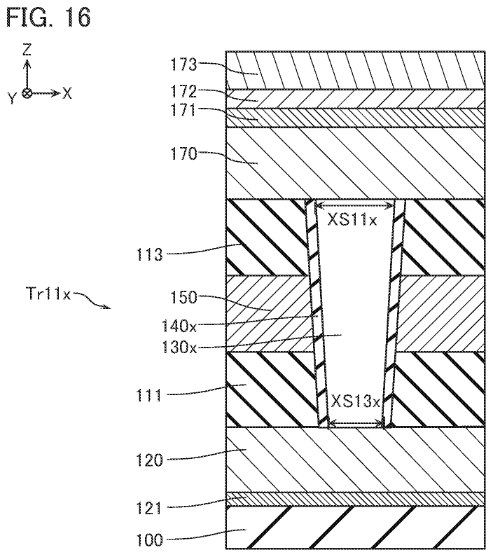

Next, for example, as illustrated in FIG. 15, a part of the semiconductor layer 130′ formed outside the part where the opening TH12 was present is removed and planarized to form the semiconductor layer 130. This process is performed by, for example, Chemical Mechanical Planarization (CMP).

Next, on the upper surface of the structure illustrated in FIG. 15, the conductive layer 170, the conductive layer 171, the conductive layer 172, and the conductive layer 173 are formed to manufacture the semiconductor device according to the first embodiment.

### Comparative Example

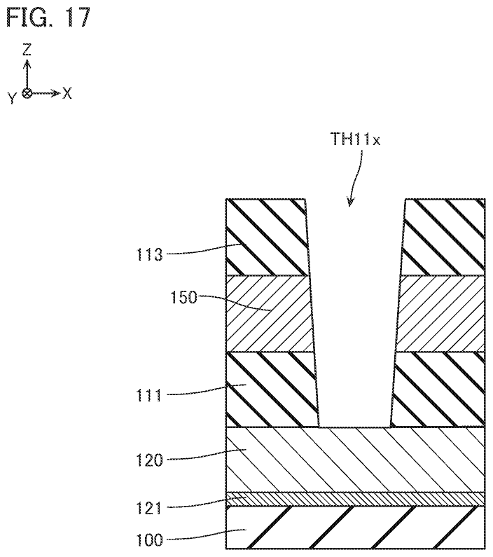

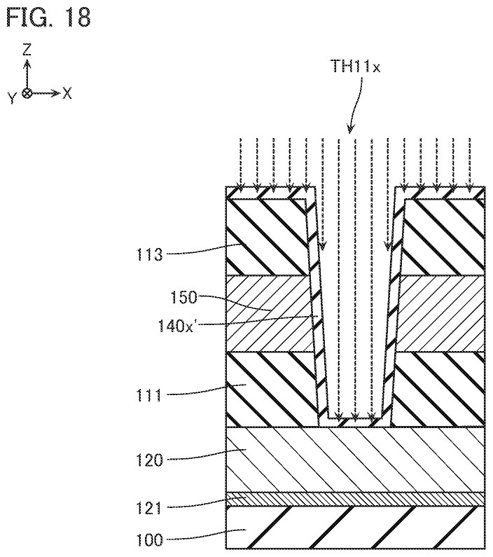

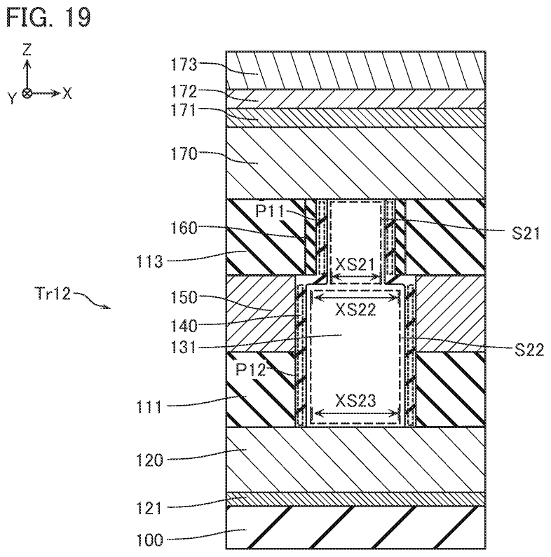

Next, with reference to FIG. 16 to FIG. 18, a semiconductor device and a manufacturing method thereof according to the comparative example will be described. FIG. 16 is a schematic cross-sectional view for describing the semiconductor device according to the comparative example. FIG. 17 and FIG. 18 are schematic cross-sectional views for describing the manufacturing method of the semiconductor device according to the comparative example and correspond to the part illustrated in FIG. 16.

The semiconductor device according to the comparative example includes a transistor structure Tr11x as illustrated in FIG. 16. The transistor structure Tr11x includes a semiconductor layer 130x and an insulating layer 140x instead of the semiconductor layer 130 and the insulating layer 140. Additionally, the transistor structure Tr11x does not include the insulating layer 160.

A width in the X-direction of the end portion on the conductive layer 120 side in the Z-direction of the semiconductor layer 130x is a width XS13x. A width in the X-direction of the end portion on the conductive layer 170 side in the Z-direction of the semiconductor layer 130x is a width XS11x. The width XS13x is smaller than the width XS11x. That is, the semiconductor layer 130x has a shape having the narrower width toward the lower side. The side surface of the semiconductor layer 130x is not perpendicular to the surface of the substrate and has a predetermined angle.

In the semiconductor device according to the comparative example, the width in the X-direction of the semiconductor layer 130x becomes smaller toward the lower side, and therefore the contacted area of the semiconductor layer 130x with the conductive layer 120 becomes comparatively small. Accordingly, there was a case where a contact resistance of the semiconductor layer 130x with the conductive layer 120 was comparatively high.

### Manufacturing Method of Comparative Example

In manufacturing the semiconductor device according to the comparative example, instead of the processes illustrated in FIG. 8 to FIG. 11, as illustrated in FIG. 17, an opening TH11x is formed in one process. The opening TH11x extends in the Z-direction and penetrates the insulating layer 113, the conductive layer 150, and the insulating layer 111 to expose the conductive layer 120. In this process, for example, an insulating layer having an opening in a part corresponding to the opening TH11x is formed on the upper surface of the structure illustrated in FIG. 7, and, for example, RIE is performed using it as a mask. Note that when the opening having the comparatively high aspect ratio is formed by RIE, as illustrated in FIG. 17, the side surface of the opening TH11x is formed to be not perpendicular to the surface of the substrate and have the predetermined angle.

Next, for example, as illustrated in FIG. 18, an insulating layer 140x′ is formed on the upper surface of the insulating layer 113 and inside the opening TH11x.

Next, in the insulating layer 140x′, the upper surface part of the insulating layer 113 and the bottom surface part of the opening TH11x are removed to form the insulating layer 140x on the inner surface of the opening TH11x. This process is performed by, for example, RIE. Note that during the RIE process, plasma active species mainly come from the direction perpendicular to the surface of the substrate (the Z-direction illustrated in FIG. 18) to collide with a processed portion.

Here, as illustrated in FIG. 18, in the semiconductor device according to the comparative example, the side surface of the opening TH11x is not perpendicular to the surface of the substrate and has the predetermined angle. In the case, comparatively many plasma active species collide with the insulating layer 140x (FIG. 16) formed on the side surface of the opening TH11x, and comparatively many damages occur in the insulating layer 140x in some cases. The damage means that, for example, a crystalline structure, such as an oxide film, contained in the insulating layer 140x is partially broken or many traps derived from a crystal defect occur in the oxide film.

Thus, in the semiconductor device according to the comparative example, many damages occur in the insulating layer 140x functioning as a gate oxide film to deteriorate reliability of the gate insulating film and significantly vary a threshold of the select transistor ST in some cases.

### Effects

In the manufacturing process of the semiconductor device according to this embodiment, in the process described with reference to FIG. 11, while the insulating layer 113 is protected by the insulating layer 160, the parts of the conductive layer 150 and the insulating layer 111 exposed to the opening TH11 are removed.

The method allows comparatively increasing the contacted area of the semiconductor layer 130 with the conductive layer 120. Accordingly, the contact resistance of the semiconductor layer 130 with the conductive layer 120 can be comparatively decreased.

With the method, in the process described with reference to FIG. 13, the part of the insulating layer 140′ covering the insulating layer 160 has the structure of protruding toward the center side of the opening TH12 with respect to the part of the insulating layer 140′ covering the conductive layer 150. This reduces collision of the above-described plasma active species with the part of the insulating layer 140′ covering the conductive layer 150 when the bottom surface part of the opening TH12 in the insulating layer 140′ is removed by RIE, and allows reducing damage due to the above-described RIE process.

Additionally, in the semiconductor device according to this embodiment, the opening TH12 is formed using the processes illustrated in FIG. 8 to FIG. 11. Here, the process described with reference to FIG. 8 can be performed in a time shorter than that of the process described with reference to FIG. 17. In view of this, the side surface of the opening TH10 (FIG. 8) is formed approximately perpendicular to the surface of the substrate.

Additionally, the process described with reference to FIG. can also be performed in a time shorter than that of the process described with reference to FIG. 17. Accordingly, in the side surface of the opening TH11 (FIG. 10), the part disposed at the height position corresponding to the insulating layer 111 and the conductive layer 150 is formed approximately perpendicular to the surface of the substrate. Additionally, the process described with reference to FIG. 10 is, as described above, performed under the condition where the insulating layer 111 and the conductive layer 150 are easily removed more than the insulating layer 160′. Therefore, in the side surface of the opening TH11, the part disposed at the height position corresponding to the insulating layer 160 is also formed approximately perpendicular to the surface of the substrate.

When the process is employed, for example, as illustrated in FIG. 13, when the insulating layer 140′ on the bottom surface part of the opening TH12 is removed by RIE, the insulating layer 140 disposed on the side surface of the opening TH12 is perpendicular to the surface of the substrate, and therefore the damage due to the RIE process as in the comparative example is less likely to be received.

Accordingly, the configuration allows reducing the deterioration of reliability of the gate insulating film in the transistor structure Tr11, reducing, for example, the variation in the threshold of the select transistor ST, and manufacturing the semiconductor device that operates preferably.

Since the semiconductor device according to this embodiment is manufactured by the method, in the contact surface of the insulating layer 140 and the semiconductor layer 130, a step including the surface SU13 is formed in a region between the surface Still corresponding to the insulating layer 160 and the surface SU12 corresponding to the insulating layer 111 and the conductive layer 150.

### Modification 1 of First Embodiment

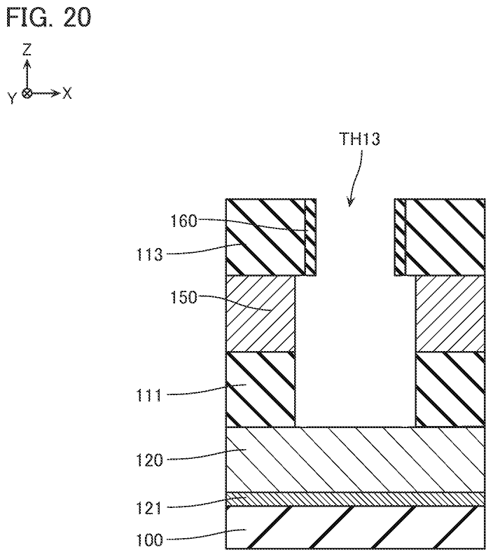

Next, with reference to FIG. 19, Modification 1 of the semiconductor device according to the first embodiment will be described. FIG. 19 is a schematic cross-sectional view illustrating a configuration of a part of the semiconductor device according to this modification. The semiconductor device according to this modification includes, for example, a transistor structure Tr12 as illustrated in FIG. 19.

[Transistor Structure Tr12]

In the transistor structure Tr12, the semiconductor layer 130 as in the transistor structure Tr11 of the first embodiment is not disposed, but a semiconductor layer 131 as illustrated in FIG. 19 is disposed. The semiconductor layer 131, for example, contains a material similar to the semiconductor layer 130.

For example, as illustrated in FIG. 19, the semiconductor layer 131 includes a region S21 having an outer peripheral surface surrounded by the part P11 of the insulating layer 140 and a region S22 having an outer peripheral surface surrounded by the part P12 of the insulating layer 140. A width in the X-direction of the end portion on the region S22 side in the Z-direction of the region S21 is a width XS21. A width in the X-direction of the end portion on the region S21 side in the Z-direction of the region S22 is a width XS22. The width XS21 is smaller than the width XS22.

Note that the width XS22 is larger than the width XS12 in the transistor structure Tr11. For example, as illustrated in FIG. 19, the side surface in the X-direction of the region S22 is disposed to the conductive layer 150 side with respect to the side surface (the side surface on the insulating layer 140 side) on the region S21 side of the insulating layer 160. That is, the width XS22 is larger than the sum of the width XS21 and twice the film thickness of the insulating layer 140. Additionally, the side surface in the X-direction of the region S22 may be disposed to the conductive layer 150 side further than the side surface on the insulating layer 113 side of the insulating layer 160. That is, the width XS22 may be larger than the sum of the width XS21, twice the film thickness of the insulating layer 140, and twice the film thickness of the insulating layer 160. That is, a distance between the side surface in the X-direction of the region S22 and the center position in the X-direction of the semiconductor layer 131 may be larger than a distance between the side surface on the insulating layer 140 side (inner peripheral side) or the insulating layer 113 side (outer peripheral side) of the insulating layer 160 and the center position in the X-direction of the semiconductor layer 131.

Note that, for example, as illustrated in FIG. 19, a width in the X-direction of the lower end portion (the end portion on the side opposite to the region S21 in the Z-direction) of the region S22 in the semiconductor layer 131 is a width XS23. The width XS23 may be the same extent of the width XS22 or may be smaller than the width XS22.

### Manufacturing Method of Modification 1 of First Embodiment

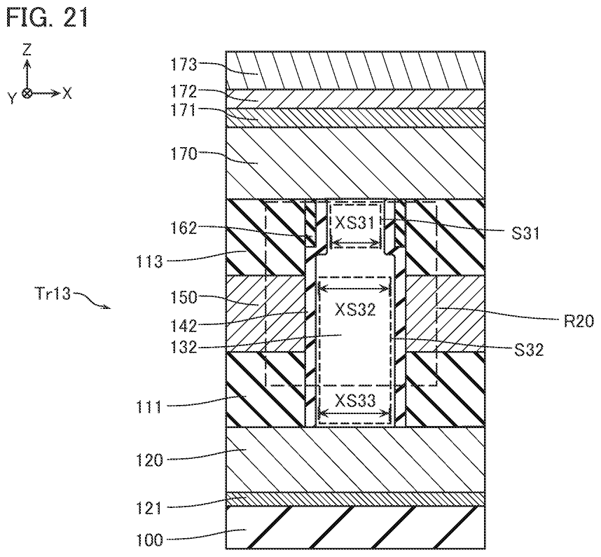

The semiconductor device according to Modification 1 of the first embodiment is manufactured basically similarly to the semiconductor device according to the first embodiment. However, in the manufacturing method of the semiconductor device according to this modification, in the process corresponding to the process described with reference to FIG. 11, the parts of the conductive layer 150 and the insulating layer 111 exposed to the opening TH11 are removed further more to form an opening TH13 as illustrated in FIG. 20. For example, etching by, for example, CDE or wet etching is proceeded until the side surfaces in the X-direction of the conductive layer 150 and the insulating layer 111 inside the opening TH13 become outside with respect to the side surface on the insulating layer 113 side of the insulating layer 160. This forms the transistor structure Tr12 as illustrated in FIG. 19.

### Modification 2 of First Embodiment

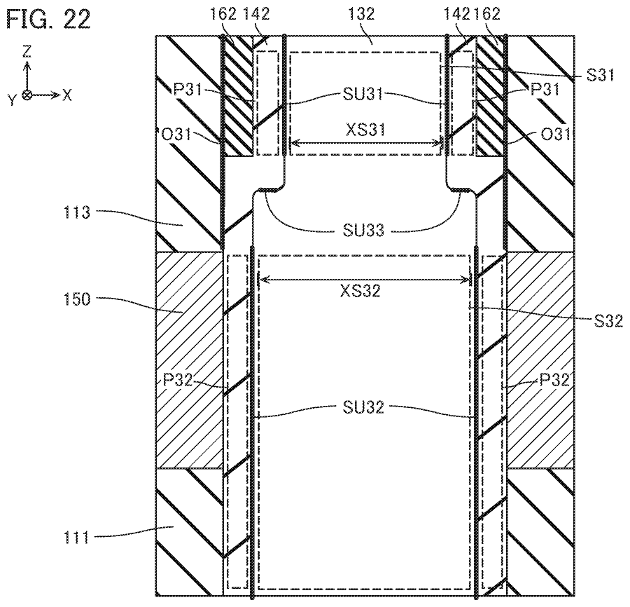

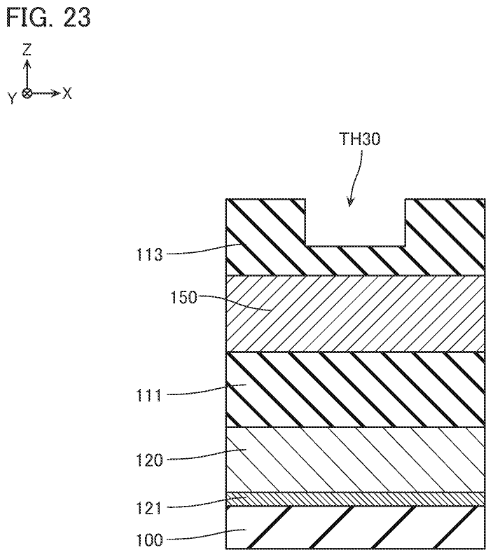

Next, with reference to FIG. 21 and FIG. 22, the semiconductor device according to Modification 2 of the first embodiment will be described. FIG. 21 is a schematic cross-sectional view illustrating a configuration of a part of the semiconductor device according to this modification. FIG. 22 is a schematic cross-sectional view illustrating an enlarged region R20 illustrated in FIG. 21. The semiconductor device according to this modification, for example, includes a transistor structure Tr13 as illustrated in FIG. 21.

[Transistor Structure Tr13]

In the transistor structure Tr13, the semiconductor layer 130, the insulating layer 140, or the insulating layer 160 as in the transistor structure Tr11 of the first embodiment is not disposed, and as illustrated in FIG. 21, the transistor structure Tr13 includes a semiconductor layer 132, the insulating layer 142, and an insulating layer 162. The semiconductor layer 132, the insulating layer 142, and the insulating layer 162, for example, contain materials similar to the semiconductor layer 130, the insulating layer 140, and the insulating layer 160, respectively.

For example, as illustrated in FIG. 21, the insulating layer 162 is disposed between the insulating layer 113 and the insulating layer 142. The insulating layer 162 covers a part positioned in the upper side in the side surface in the X-direction of the insulating layer 113 and does not cover the part positioned on the lower side. The insulating layer 113 contacts the insulating layer 162 and the insulating layer 142. That is, for example, as illustrated in FIG. 22, a surface O31 as an opposed surface to the semiconductor layer 132 of the insulating layer 113 includes a region in contact with the insulating layer 162 and a region in contact with the insulating layer 142. Additionally, the length in the Z-direction of the insulating layer 162 is shorter than the length in the Z-direction of the insulating layer 113.

For example, as illustrated in FIG. 22, the insulating layer 142 includes a part P31 that covers a part of the side surface in the X-direction of the insulating layer 113 via the insulating layer 162. Additionally, the insulating layer 142 includes a part P32 that is in contact with the insulating layer 111 and the conductive layer 150 and covers the side surfaces in the X-direction of the insulating layer 111 and the conductive layer 150. Each of the part P31 and the part P32 extends in the Z-direction.

In the contact surface of the insulating layer 142 with the semiconductor layer 132, a region corresponding to the part P31 is referred to as a surface SU31 and a region corresponding to the part P32 is referred to as a surface SU32. In this embodiment, a surface SU33 is disposed in the region between the surface SU31 and the surface SU32. The surface SU33 extends in a direction different from the extension direction (the Z-direction in the example of FIG. 22) of the part P31 and the part P32. For example, in the example of FIG. 22, the surface SU33 extends in the X-direction.

For example, as illustrated in FIG. 22, the semiconductor layer 132 includes a region S31 having an outer peripheral surface surrounded by the part P31 of the insulating layer 142 and a region S32 having an outer peripheral surface surrounded by the part P32 of the insulating layer 142. A width in the X-direction of the lower end portion (the end portion on the region S32 side in the Z-direction) of the region S31 is a width XS31. A width in the X-direction of the upper end portion (the end portion on the region S31 side in the Z-direction) of the region S32 is a width XS32. The width XS31 is smaller than the width XS32.

Additionally, for example, as illustrated in FIG. 21, a width in the X-direction of the lower end portion (the end portion on the side opposite to the region S31 in the Z-direction) of the region S32 in the semiconductor layer 132 is a width XS33. The width XS33 may be the same extent to the width XS32 or may be smaller than the width XS32.

### Manufacturing Method of Modification 2 of First Embodiment

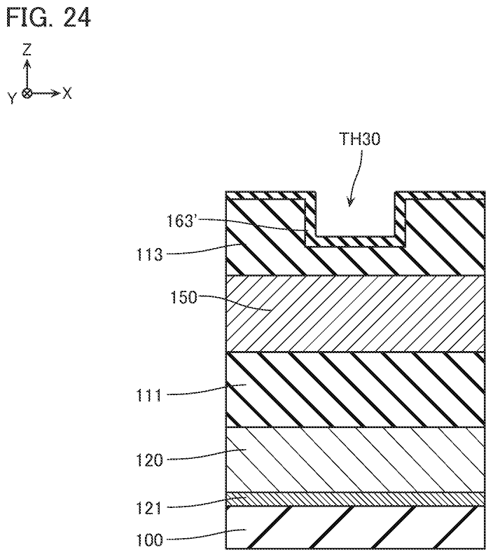

The semiconductor device according to Modification 2 of the first embodiment is manufactured basically similarly to the semiconductor device according to the first embodiment. However, in the manufacturing method of the semiconductor device according to this modification, in a process corresponding to the process described with reference to FIG. 8, as illustrated in FIG. 23, an opening TH30 shallower than the opening TH10 is formed in the insulating layer 113. The opening TH30 extends inside the insulating layer 113 in the Z-direction but does not expose the conductive layer 150.

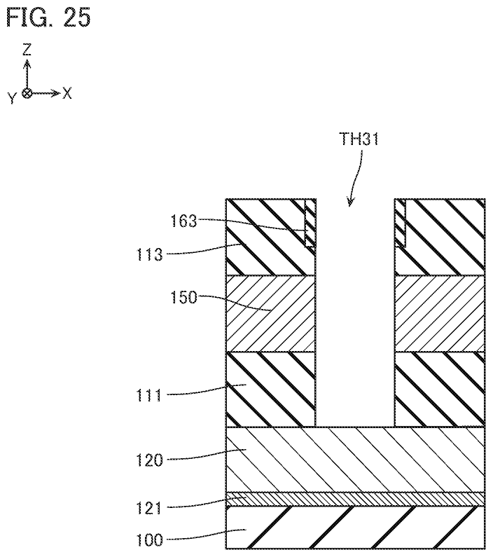

Next, for example, as illustrated in FIG. 24, in the process corresponding to the process described with reference to FIG. 9, an insulating layer 163′ is formed on the upper surface of the insulating layer 113 and inside the opening TH30. The insulating layer 163′, for example, contains a material similar to an insulating layer 163.

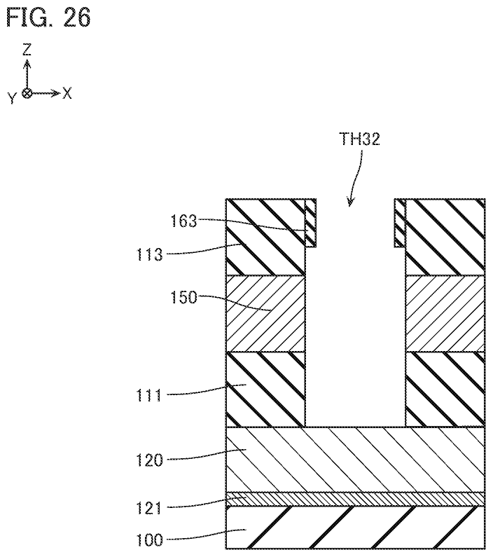

Next, for example, in the process corresponding to the process described with reference to FIG. 10, as illustrated in FIG. 25, an opening TH31 is formed in the part where the opening TH30 was present. The opening TH31 extends in the Z-direction and penetrates the insulating layer 113, the conductive layer 150, and the insulating layer 111 to expose the conductive layer 120. In this process, in the insulating layer 163′, the upper surface part of the insulating layer 113 and the bottom surface part of the opening TH30 are removed, and the insulating layer 163 is formed on a part of the side surface of the insulating layer 113 inside the opening TH31.

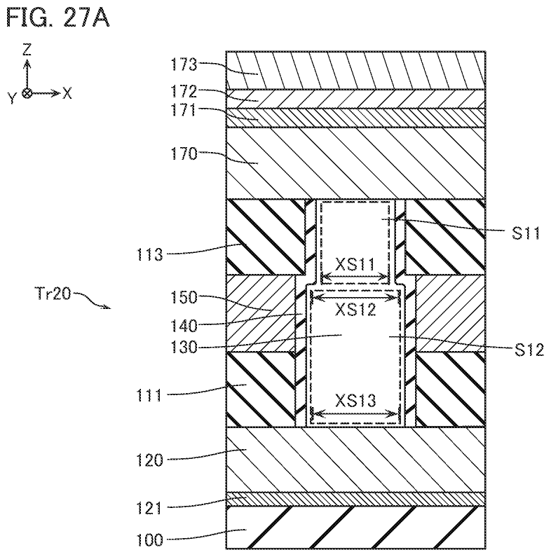

Next, for example, in the process corresponding to the process described with reference to FIG. 11, as illustrated in FIG. 26, via the opening TH31, the parts of the insulating layer 113, the conductive layer 150, and the insulating layer 111 exposed to the opening TH31 are removed to form an opening TH32. Note that, in this process, the part of the insulating layer 113 protected by the insulating layer 160 is not etched.

Next, for example, the processes corresponding to the processes described with reference to FIG. 12 to FIG. 15 are performed to manufacture the semiconductor device according to this modification.

### Second Embodiment

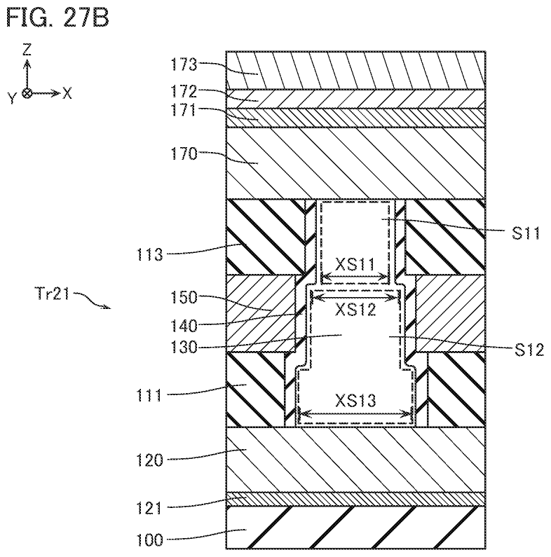

Next, using FIG. 27A and FIG. 27B, a semiconductor device according to the second embodiment will be described. FIG. 27A and FIG. 27B are schematic cross-sectional views for describing the semiconductor device according to the second embodiment. In the following description, the same reference numerals are given to the configurations similar to those of the first embodiment, and the description thereof will be omitted.

[Transistor Structures Tr20, Tr21]

The semiconductor device according to the second embodiment is configured basically similarly to the semiconductor device according to the first embodiment. However, in the transistor structures Tr20, Tr21 according to this embodiment, for example, as illustrated in FIG. 27A and FIG. 27B, the insulating layer 160 is not disposed in a position of covering a part of the outer peripheral surface of the insulating layer 140. Note that, for example, in the transistor structure Tr20 as illustrated in FIG. 27A, the width XS13 may be the same extent to the width XS12. Additionally, for example, in the transistor structure Tr21 as illustrated in FIG. 27B, the width XS13 may be larger than the width XS12.

### Manufacturing Method of Second Embodiment

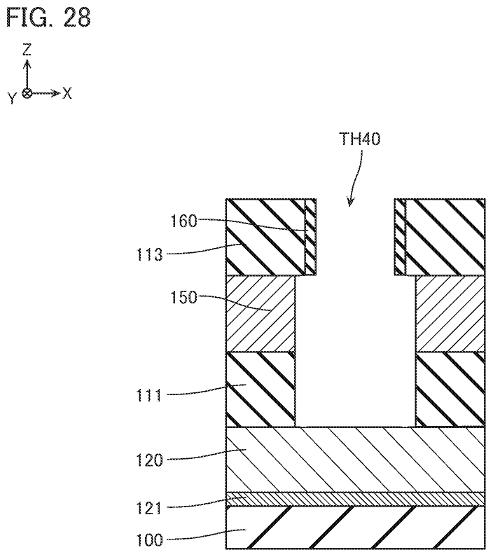

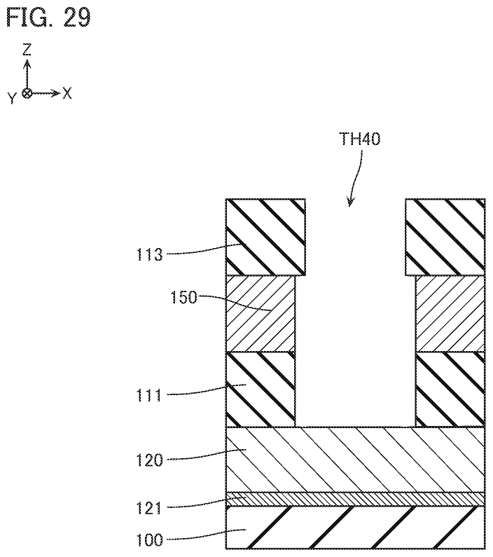

Next, with reference to FIG. 28 and FIG. 29, the manufacturing method of the semiconductor device according to this embodiment will be described. FIG. 28 and FIG. 29 are schematic cross-sectional views for describing the manufacturing method of the semiconductor device according to this embodiment and correspond to the part illustrated in FIG. 27A and FIG. 27B.

In the manufacturing method, first, the processes similar to the processes described with reference to FIG. 7 to FIG. 10 in the first embodiment are performed.

Next, for example, as illustrated in FIG. 28, via the opening TH11, the parts of the conductive layer 150 and the insulating layer 111 exposed to the opening TH11 are removed to form an opening TH40. In this process, etching by, for example, CDE or wet etching is proceeded until the side surfaces in the X-direction of the conductive layer 150 and the insulating layer 111 inside the opening TH40 become outside with respect to the side surface on the insulating layer 113 side of the insulating layer 160. Note that in this process, the side surface in the X-direction of the insulating layer 111 inside the opening TH40 may be formed to be at the position similar to the side surface in the X-direction of the conductive layer 150 inside the opening TH40. In the case, like the transistor structure Tr20, the structure in which the width XS13 becomes the same extent to the width XS12 is formed (FIG. 27A). Additionally, in this process, the side surface in the X-direction of the insulating layer 111 inside the opening TH40 may be formed to be outside with respect to the side surface in the X-direction of the conductive layer 150 inside the opening TH40. In the case, like the transistor structure Tr21, the structure in which the width XS13 is larger than the width XS12 is formed (FIG. 27B).

Next, for example, as illustrated in FIG. 29, via the opening TH40, the insulating layer 160 is removed. This process is performed by, for example, CDE or wet etching.

Next, for example, the processes corresponding to the processes described with reference to FIG. 12 to FIG. 15 are performed to manufacture the semiconductor device according to this embodiment.

Here, as described above, the process described with reference to FIG. 10 is performed under the condition where the insulating layer 111 and the conductive layer 150 are easily removed more than the insulating layer 160′. Therefore, in the side surface of the opening TH11, the part disposed at the height position corresponding to the insulating layer 160 is formed at an angle close to be perpendicular. However, as illustrated in FIG. 29, by removing the insulating layer 160 after forming the opening TH40, in the side surface of the opening TH40, the part disposed at the height position corresponding to the insulating layer 113 can be formed at the angle further close to be perpendicular to the surface of the substrate.

### Third Embodiment

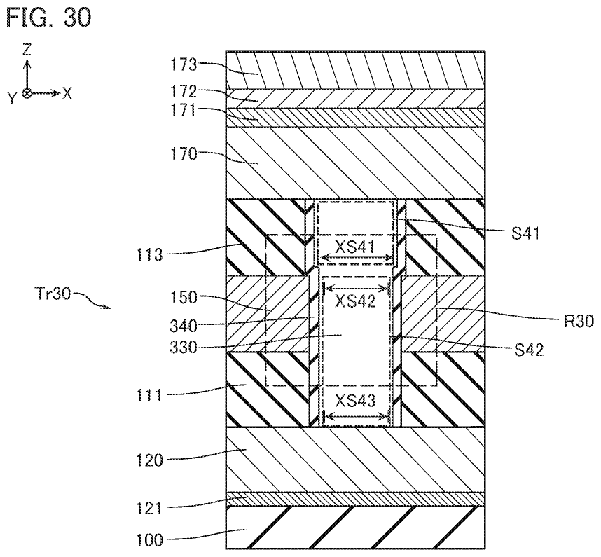

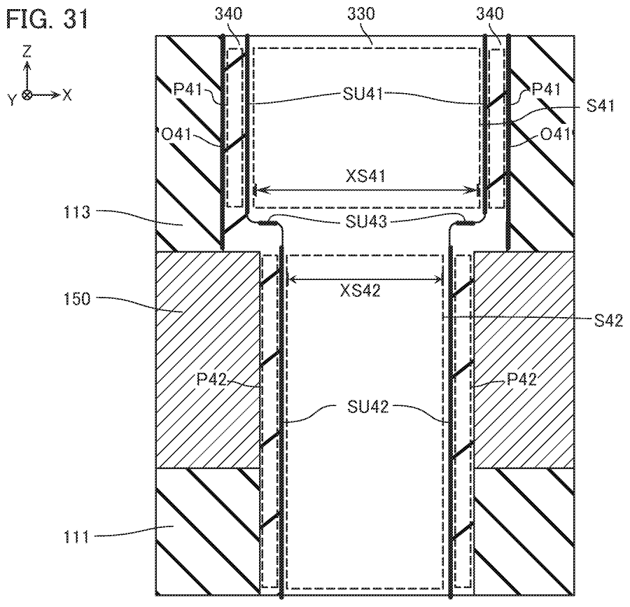

Next, using FIG. 30 and FIG. 31, a semiconductor device according to the third embodiment will be described. FIG. 30 is a schematic cross-sectional view for describing the semiconductor device according to this embodiment. FIG. 31 is a schematic cross-sectional view illustrating an enlarged region R30 illustrated in FIG. 30. In the following description, the same reference numerals are given to the configurations similar to those of the first embodiment, and the description thereof will be omitted.

[Transistor Structure Tr30]

The semiconductor device according to the third embodiment is configured basically similarly to the semiconductor device according to the first embodiment. However, for example, as illustrated in FIG. 30, the insulating layer 160 is not disposed in the transistor structure Tr30 according to this embodiment.

Additionally, the transistor structure Tr30 includes a semiconductor layer 330 and an insulating layer 340 instead of the semiconductor layer 130 and the insulating layer 140 in the transistor structure Tr11. For example, as illustrated in FIG. 31, a surface O41 as an opposed surface to the semiconductor layer 330 of the insulating layer 113 is disposed so as to contact the insulating layer 340. The semiconductor layer 330 and the insulating layer 340, for example, contain materials similar to the semiconductor layer 130 and the insulating layer 140, respectively.

For example, as illustrated in FIG. 30 and FIG. 31, the insulating layer 340 includes a part P41 that is in contact with the insulating layer 113 and covers the side surface in the X-direction of the insulating layer 113. Additionally, the insulating layer 340 includes a part P42 that is in contact with the insulating layer 111 and the conductive layer 150 and covers the side surfaces in the X-direction of the insulating layer 111 and the conductive layer 150. Each of the part P41 and the part P42 extends in the Z-direction.

In the contact surface of the insulating layer 340 with the semiconductor layers 330, a region corresponding to the part P41 is referred to as a surface SU41 and a region corresponding to the part P42 is referred to as a surface SU42. Additionally, in this embodiment, a surface SU43 is disposed in a region between the surface SU41 and the surface SU42. The surface SU43 extends in a direction different from the extending direction (the Z-direction in the example of FIG. 31) of the part P41 and the part P42. For example, in the example illustrated in FIG. 31, the surface SU43 extends in the X-direction.

For example, as illustrated in FIG. 31, the semiconductor layer 330 includes a region S41 having an outer peripheral surface surrounded by the part P41 of the insulating layer 340 and a region S42 having an outer peripheral surface surrounded by the part P42 of the insulating layer 340. A width in the X-direction of the lower end portion (the end portion on the region S42 side in the Z-direction) of the region S41 is a width XS41. A width in the X-direction of the upper end portion (the end portion on the region S41 side in the Z-direction) of the region S42 is a width XS42. The width XS41 is larger than the width XS42.

Note that, for example, as illustrated in FIG. 30, a width in the X-direction of the lower end portion (the end portion on the side opposite to the region S41 in the Z-direction) of the region S42 in the semiconductor layer 330 is a width XS43. The width XS43 may be the same extent to the width XS42 or may be smaller than the width XS42.

In the description above, for example, the transistor structure Tr30 in the XZ cross-sectional surface as illustrated in FIG. 30 and FIG. 31 has been exemplified. However, the transistor structure Tr30 may have the similar configuration in a YZ cross-sectional surface (not illustrated).

### Manufacturing Method of Third Embodiment

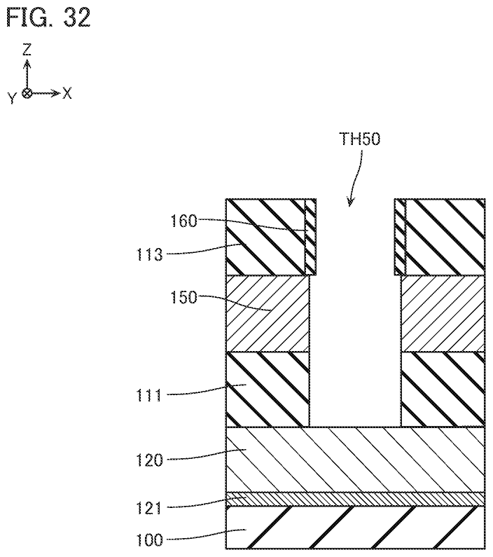

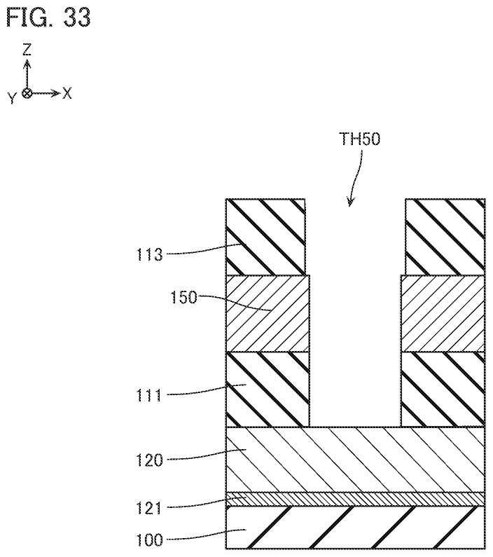

Next, with reference to FIG. 32 and FIG. 33, the manufacturing method of the semiconductor device according to this embodiment will be described. FIG. 32 and FIG. 33 are schematic cross-sectional views for describing the manufacturing method of the semiconductor device according to the third embodiment and correspond to the part illustrated in FIG. 30.

In the manufacturing method, first, the processes similar to the processes described with reference to FIG. 7 to FIG. 10 in the first embodiment are performed.

Next, for example, as illustrated in FIG. 32, via the opening TH11, the parts of the conductive layer 150 and the insulating layer 111 exposed to the opening TH11 are removed to form an opening TH50. In this process, etching by, for example, CDE or wet etching is proceeded to the extent that the side surfaces in the X-direction of the conductive layer 150 and the insulating layer 111 inside the opening TH50 become inside with respect to the side surface on the insulating layer 113 side of the insulating layer 160.

Next, for example, as illustrated in FIG. 33, via the opening TH50, the insulating layer 160 is removed. This process is performed by, for example, CDE or wet etching.

Next, for example, the process similar to the process described with reference to FIG. 12 and FIG. 13 is performed to form the insulating layer 340 inside the opening TH50.

Next, for example, the process similar to the process described with reference to FIG. 14 and FIG. 15 is performed to form the semiconductor layer 330 inside the opening TH50.

Next, on the upper surfaces of the insulating layer 113 and the semiconductor layer 330, the conductive layer 170, the conductive layer 171, the conductive layer 172, and the conductive layer 173 are formed to manufacture the semiconductor device according to the third embodiment.

In the third embodiment, similarly to the second embodiment, in the side surface of the opening TH50, the part disposed at the height position corresponding to the insulating layer 113 can be formed at the angle further close to be perpendicular to the surface of the substrate.

### Fourth Embodiment

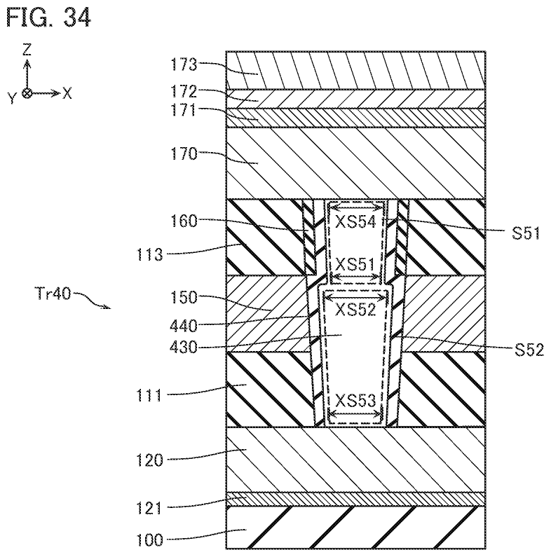

Next, using FIG. 34, a semiconductor device according to the fourth embodiment will be described. FIG. 34 is a schematic cross-sectional view for describing the semiconductor device according to this embodiment. In the following description, the same reference numerals are given to the configurations similar to those of the first embodiment, and the description thereof will be omitted.

[Transistor Structure Tr40]

In the transistor structure Tr40, the semiconductor layer 130 or the insulating layer 140 as in the transistor structure Tr11 of the first embodiment is not disposed, but a semiconductor layer 430 and an insulating layer 440 as illustrated in FIG. 34 are disposed. The semiconductor layer 430 and the insulating layer 440, for example, contain materials similar to the semiconductor layer 130 and the insulating layer 140, respectively.

For example, as illustrated in FIG. 34, the semiconductor layer 430 includes a region S51 disposed at a position corresponding to the insulating layer 113 and a region S52 disposed at a position corresponding to the insulating layer 111 and the conductive layer 150. A width in the X-direction of the upper end portion (the end portion on the conductive layer 170 side in the Z-direction) of the region S51 is a width XS54. A width in the X-direction of the lower end portion (the end portion on the region S52 side in the Z-direction) of the region S51 is a width XS51. A width in the X-direction of the upper end portion (the end portion on the region S51 side in the Z-direction) of the region S52 is a width XS52. A width in the X-direction of the lower end portion (the end portion on the side opposite to the region S51 in the Z-direction) of the region S52 is a width XS53. For example, as illustrated in FIG. 34, the width XS51 is smaller than the width XS54 and the width XS53 is smaller than the width XS52. The width XS51 is smaller than the width XS52. That is, the region S51 and the region S52 of the semiconductor layer 430 have shapes having the narrower width toward the lower side.

### Manufacturing Method of Fourth Embodiment

The semiconductor device according to the fourth embodiment is manufactured basically similarly to the semiconductor device according to the first embodiment. However, in the processes described with reference to FIG. 8 and FIG. 10, the opening TH10 and the opening TH11 are formed as the shapes having the narrower width toward the lower side.

[Effects]

The side surface of the insulating layer 440 is not perpendicular to the surface of the substrate and has a predetermined angle. On the other hand, the part of the insulating layer 440 covering the insulating layer 160 has the structure of protruding toward the center side of the semiconductor layer 430 with respect to the part of the insulating layer 440 covering the conductive layer 150. In the case, for example, a process of removing the bottom surface part of the opening TH12 in the insulating layer 140′ by RIE in the process described with reference to FIG. 13 in the case will be described. In this process, in this embodiment, the side surface of the insulating layer 440 has the predetermined angle. However, by the part of the insulating layer 440 covering the insulating layer 160, collision of the above-described plasma active species with the part of the insulating layer 140′ covering the conductive layer 150 is reduced, and therefore damage due to the RIE process can be reduced.

### Other Embodiments

The semiconductor devices according to the first embodiment to the fourth embodiment have been described above. However, the semiconductor devices according to these embodiments are only examples, and a specific configuration, operations, and the like are adjustable as appropriate.

For example, in the above description, the example in which the capacitor Cap is connected to the select transistor ST has been described. In the example, for example, the shape and the structure of the capacitor Cap are adjustable as appropriate.

Additionally, in the above description, the example in which the capacitor Cap is employed as the memory portion connected to the select transistor ST has been described. However, the memory portion need not be the capacitor Cap. For example, the memory portion may contain a ferroelectric material, a ferromagnet material, a chalcogen material such as GeSbTe, or another material and may store data using the characteristics of these materials. For example, in any of the structures described above, any of these materials may be contained in the insulating layer between the electrodes forming the capacitor Cap.

Additionally, in the above description, for example, as described with reference to FIG. 10 or the like, the example in which after the insulating layer 111 and the conductive layer 150 are processed by the method, such as RIE, as described with reference to FIG. 11, parts of the insulating layer 111 and the conductive layer 150 are removed by the method, such as wet etching, has been described. However, for example, after the conductive layer 150 is processed by the method, such as RIE, before the insulating layer 111 is processed by the method, such as RIE, a part of the conductive layer 150 may be removed by the method, such as wet etching. This method allows reducing the collision of the above-described plasma active species with the side surface of the conductive layer 150 when the insulating layer 111 is processed by the method, such as RIE. Thus, in the side surface of the opening TH12 (FIG. 11), the part disposed at the height position corresponding to the insulating layer 111 and the conductive layer 150 can be formed at the angle further close to be perpendicular to the surface of the substrate.

### [Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device comprising:
a first insulating layer and a second insulating layer arranged in a first direction;
a first conductive layer disposed between the first insulating layer and the second insulating layer;
an oxide semiconductor layer extending in the first direction, the oxide semiconductor layer being opposed to the first insulating layer, the second insulating layer, and the first conductive layer in a second direction intersecting with the first direction; and
a third insulating layer disposed between the first insulating layer and the oxide semiconductor layer, between the second insulating layer and the oxide semiconductor layer, and between the first conductive layer and the oxide semiconductor layer, wherein
the third insulating layer includes:
a first part that covers at least a part of a side surface in the second direction of the first insulating layer; and
a second part that covers at least a part of side surfaces in the second direction of the second insulating layer and the first conductive layer, and
a first region extending in a direction different from an extending direction of the first part and an extending direction of the second part is disposed between a region corresponding to the first part and a region corresponding to the second part, and is in contact with the third insulating layer and the oxide semiconductor layer.

2. The semiconductor device according to claim 1, wherein
the oxide semiconductor layer includes:
a first semiconductor region having an outer peripheral surface surrounded by the first part of the third insulating layer; and
a second semiconductor region having an outer peripheral surface surrounded by the second part of the third insulating layer, and
when a width in the second direction of an end portion of the first semiconductor region is assumed to be a first width, the end portion of the first semiconductor region being in contact with the second semiconductor region; and
when a width in the second direction of an end portion of the second semiconductor region is assumed to be a second width, the end portion of the second semiconductor region being in contact with the first semiconductor region,
the first width is smaller than the second width.

3. The semiconductor device according to claim 2, wherein
when a width in the second direction of an end portion of the second semiconductor region is assumed to be a third width, the end portion being far from the first semiconductor region, the third width is smaller than the second width.

4. The semiconductor device according to claim 2, wherein
when a width in the second direction of an end portion of the second semiconductor region is assumed to be a third width, the end portion being far from the first semiconductor region, the third width is larger than the second width.

5. The semiconductor device according to claim 1, wherein
the oxide semiconductor layer includes:
a first semiconductor region having an outer peripheral surface surrounded by the first part of the third insulating layer; and
a second semiconductor region having an outer peripheral surface surrounded by the second part of the third insulating layer, and
when a width in the second direction of an end portion of the first semiconductor region is assumed to be a first width, the end portion of the first semiconductor region being in contact with the second semiconductor region; and
when a width in the second direction of an end portion of the second semiconductor region is assumed to be a second width, the end portion of the second semiconductor region being in contact with the first semiconductor region,
the first width is larger than the second width.

6. The semiconductor device according to claim 1, comprising
a fourth insulating layer disposed between the first insulating layer and the third insulating layer, the fourth insulating layer having at least one of a material different from a material of the first insulating layer or a film density different from a film density of the first insulating layer.

7. The semiconductor device according to claim 6, wherein
an opposed surface of the first insulating layer to the oxide semiconductor layer is not in contact with the third insulating layer.

8. The semiconductor device according to claim 6, wherein
an opposed surface of the first insulating layer to the oxide semiconductor layer includes:
a region in contact with the fourth insulating layer; and
a region in contact with the third insulating layer.

9. The semiconductor device according to claim 6, wherein
the second insulating layer and the first conductive layer are in contact with the third insulating layer.

10. The semiconductor device according to claim 6, wherein
the fourth insulating layer surrounds an outer peripheral surface of the third insulating layer in a first cross-sectional surface that extends in the second direction and a third direction intersecting with the first direction and the second direction and includes the first insulating layer.

11. The semiconductor device according to claim 1, comprising
a second conductive layer connected to one end portion in the first direction of the oxide semiconductor layer, wherein
the second conductive layer contains indium (In) and tin (Sn).

12. A semiconductor device comprising:
a first insulating layer and a second insulating layer arranged in a first direction;
a first conductive layer disposed between the first insulating layer and the second insulating layer;
an oxide semiconductor layer extending in the first direction, the oxide semiconductor layer being opposed to the first insulating layer, the second insulating layer, and the first conductive layer in a second direction intersecting with the first direction;
a third insulating layer disposed between the first insulating layer and the oxide semiconductor layer, between the second insulating layer and the oxide semiconductor layer, and between the first conductive layer and the oxide semiconductor layer; and
a fourth insulating layer disposed between the first insulating layer and the third insulating layer, the fourth insulating layer having at least one of a material different from a material of the first insulating layer or a film density different from a film density of the first insulating layer.

13. The semiconductor device according to claim 12, wherein
an opposed surface of the first insulating layer to the oxide semiconductor layer is not in contact with the third insulating layer.

14. The semiconductor device according to claim 12, wherein
an opposed surface of the first insulating layer to the oxide semiconductor layer includes:
a region in contact with the fourth insulating layer; and
a region in contact with the third insulating layer.

15. The semiconductor device according to claim 12, wherein
the second insulating layer and the first conductive layer are in contact with the third insulating layer.

16. The semiconductor device according to claim 12, wherein
the first insulating layer and the fourth insulating layer contain silicon (Si) and oxygen (O), and
the film density of the first insulating layer differs from the film density of the fourth insulating layer.

17. The semiconductor device according to claim 12, wherein
the third insulating layer includes:
a first part that covers at least a part of a side surface in the second direction of the fourth insulating layer; and
a second part that covers at least a part of side surfaces in the second direction of the second insulating layer and the first conductive layer,
the oxide semiconductor layer includes:
a first semiconductor region having an outer peripheral surface surrounded by the first part of the third insulating layer; and
a second semiconductor region having an outer peripheral surface surrounded by the second part of the third insulating layer, and
when a width in the second direction of an end portion of the first semiconductor region is assumed to be a first width, the end portion of the first semiconductor region being in contact with the second semiconductor region; and
when a width in the second direction of an end portion of the second semiconductor region is assumed to be a second width, the end portion of the second semiconductor region being in contact with the first semiconductor region,
the first width is smaller than the second width.

18. The semiconductor device according to claim 12, wherein
an opposed surface of the first insulating layer to the oxide semiconductor layer includes:
a region in contact with the fourth insulating layer; and
a region in contact with the third insulating layer.

19. The semiconductor device according to claim 12, wherein
the fourth insulating layer surrounds an outer peripheral surface of the third insulating layer in a first cross-sectional surface that extends in the second direction and a third direction intersecting with the first direction and the second direction and includes the first insulating layer.

20. The semiconductor device according to claim 12, comprising
a second conductive layer connected to one end portion in the first direction of the oxide semiconductor layer, wherein
the second conductive layer contains indium (In) and tin (Sn).
